(19) United States
(12) Patent Application Publication
(10) Pub. No.: US 2026/0028553 A1
(43) Pub. Date: Jan. 29, 2026

(54) PROCESSING SOLUTION, METHOD FOR MANUFACTURING PROCESSING SOLUTION, METHOD FOR PROCESSING SUBSTRATE, AND METHOD FOR MANUFACTURING SEMICONDUCTOR DEVICE

(71) Applicant: TOKYO OHKA KOGYO CO., LTD., Kanagawa (JP)

(72) Inventor: Shingo ISHIDA, Kanagawa (JP)

(21) Appl. No.: 19/272,195

(22) Filed: Jul. 17, 2025

Related U.S. Application Data
(60) Provisional application No. 63/675,921, filed on Jul. 26, 2024.

(51) Int. Cl. C11D 3/00; H01L 21/02; H01L 21/3213

(52) U.S. Cl. CPC C11D 3/0073; C11D 3/0084; H01L 21/02068; C11D 2111/22; H01L 21/32136

(57) ABSTRACT

There are provided a processing solution containing an alkali compound, water, and a corrosion inhibitor, in which the amount of dissolved oxygen one week after the preparation of the processing solution is 0.2 mg/L or more and 1.5 mg/L or less, and the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof, a method for manufacturing the processing solution, and a method for processing a substrate and a method for manufacturing a semiconductor device using the processing solution.

### CROSS-REFERENCE TO RELATED APPLICATIONS

The present application claims priority to U.S. Provisional application No. 63/675,921, filed with the United States Patent and Trademark Office on Jul. 26, 2024, the entire content of which is incorporated herein by reference.

### BACKGROUND OF THE INVENTION

### Technical Field

The present invention relates to a processing solution, a method for manufacturing a processing solution, a method for processing a substrate, and a method for manufacturing a semiconductor device.

### Description of the Related Art

In a manufacturing process of a semiconductor substrate, a method for forming wiring by performing a patterning process on a substrate on which various metal layers are laminated is performed. In the wiring forming process, unnecessary resist films, embedding materials, and etching residues are removed using a processing solution so as not to interfere with the next process. Examples of the etching residues to be removed may include residues containing a metal.

As a technique related to such a processing solution, for example, Patent Document 1 (JP 2004-103771 A) discloses a cleaning solution used for removing a sacrificial layer remaining in a first etching space after forming the first etching space by etching a low-dielectric layer (Low-k layer) laminated on a substrate having a metal layer, filling the first etching space with a sacrificial layer, and further partially etching the low-dielectric layer and the sacrificial layer to form a second etching space communicating with the first etching space in formation of a dual damascene structure, the cleaning solution containing (a) 1 to 25% by mass of a quaternary ammonium hydroxide, (b) 30 to 70% by mass of a water-soluble organic solvent, and (c) 20 to 60% by mass of water.

Patent Document 2 (JP 2006-527783 A) discloses a peeling cleaning solution containing a quaternary ammonium hydroxide, a water-soluble organic solvent, water, an anticorrosive agent, and 1% by mass or less of potassium hydroxide with respect to the total amount.

### PATENT LITERATURE

Patent Document 1: JP 2004-103771 A
Patent Document 2: JP 2006-527783 A

### SUMMARY OF THE INVENTION

However, the conventional processing solution described above has a problem of damaging (corroding) the substrate having the metal layer even when the resist film, the embedding material, and the metal residue can be removed. For example, the case where a substrate having a metal layer containing Cu atoms or a substrate containing Cu atoms is processed will be described, even when a resist film, an embedding material, and a residue can be removed to some extent, the metal layer or the substrate may be damaged.

The present invention has been made in view of the above circumstances, and an object of the present invention is to provide a processing solution having excellent removability of metal components and residues to be removed and also having excellent anticorrosion properties of a metal containing Cu atoms, a method for manufacturing the processing solution, and a method for processing a substrate and a method for manufacturing a semiconductor device using the processing solution.

As a result of intensive studies to achieve the object described above, the present inventor has found that the processing solution is a processing solution containing an alkali compound, water, and a corrosion inhibitor, the amount of dissolved oxygen one week after the preparation of the processing solution is 0.2 mg/L or more and 1.5 mg/L or less, and the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof, thereby completing the present invention.

That is, the present invention is as follows.
<1>

A processing solution containing an alkali compound, water, and a corrosion inhibitor, in which the amount of dissolved oxygen one week after the preparation of the processing solution is 0.2 mg/L or more and 1.5 mg/L or less, and the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof.
<2>

The processing solution according to <1>, further containing an antioxidant.
<3>

The processing solution according to <1>, in which a content of the alkali compound is more than 10% by mass and 20% by mass or less.
<4>

The processing solution according to <1>, in which a content of the water is 50% by mass or more and 85% by mass or less.
<5>

The processing solution according to <1>, in which a content of the corrosion inhibitor is 0.005% by mass or more and 5% by mass or less.
<6>

The processing solution according to <2>, in which a content of the antioxidant is 0.001% by mass or more and 5% by mass or less.
<7>

The processing solution according to <1>, in which the amount of dissolved oxygen at the time of preparation of the processing solution is 0.2 mg/L or more and 6 mg/L or less.
<8>

The processing solution according to <1>, in which the processing solution is a processing solution for processing a substrate having a metal layer, and the substrate and/or the metal layer contain Cu atoms.
<9>

The processing solution according to <8>, in which the processing solution is used for removing a residue generated after an etching process is performed on the substrate having the metal layer.
<10>

A method for manufacturing a processing solution, the method including: a preparation step of preparing a processing solution by mixing an alkali compound, water, and a corrosion inhibitor, in which the amount of dissolved oxygen one week after the preparation of the processing solution is 0.2 mg/L or more and 1.5 mg/L or less, and the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof.
<11>

The method for manufacturing a processing solution according to <10>, in which the amount of dissolved oxygen when performing the preparation step of the processing solution is 0.2 mg/L or more and 6 mg/L or less.
<12>

A method for processing a substrate, the method including: preparing a substrate having a metal layer; etching the metal layer; and after the etching, bringing the processing solution according to <1> into contact with the substrate to remove impurities from the substrate.
<13>

A method for manufacturing a semiconductor device, the method including: preparing a substrate having a metal layer; etching the metal layer; and after the etching, bringing the processing solution according to <1> into contact with the substrate to remove impurities from the substrate.

According to the present invention, it is possible to provide a processing solution having excellent removability of metal components and residues to be removed and also having excellent anticorrosion properties of a metal containing Cu atoms, a method for manufacturing the processing solution, and a method for processing a substrate and a method for manufacturing a semiconductor device using the processing solution.

### DETAILED DESCRIPTION

Hereinafter, modes for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

### <Processing Solution>

A processing solution according to the present embodiment is a processing solution containing an alkali compound, water, and a corrosion inhibitor, in which the amount of dissolved oxygen one week after the preparation of the processing solution is 0.2 mg/L or more and 1.5 mg/L or less, and the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof. Note that the processing solution according to the present embodiment may be referred to as a cleaning solution, a peeling solution, or the like.

The processing solution according to the present embodiment is not only excellent in removability of metal components and residues to be removed, but also excellent in anticorrosion properties of a metal containing Cu atoms. As for the anticorrosion properties, for example, damage to a metal layer containing Cu atoms and a substrate containing Cu atoms can be suppressed. In addition, as for removability, for example, metal components to be removed, such as a resist film and an embedding material, and residues by etching or the like can be removed (however, the mechanism and effect according to the present embodiment are not limited thereto).

Furthermore, the processing solution according to the present embodiment is expected to suppress damage to a Low-k material and the like. For example, on a substrate on which the above-described metal layer containing Cu atoms is wired, a low-dielectric film such as a Low-k film may also be formed. According to the processing solution according to the present embodiment, it can be expected to remove the resist film, the embedding material, and the metal residue while suppressing the damage to the Low-k film.

Hereinafter, each component, physical properties, and the like of the processing solution according to the present embodiment will be described.

### (Alkali Compound)

The processing solution according to the present embodiment contains an alkali compound. The alkali compound is not particularly limited as long as it exhibits basicity when dissolved in water, and both an organic alkali compound and an inorganic alkali compound can be used.

Examples of the organic alkali compound may include quaternary ammonium salts such as an organic quaternary ammonium hydroxide; alkanolamine; and organic amines other than the alkanolamine such as a primary amine, a secondary amine, a tertiary amine, and an amidine.

Examples of the organic quaternary ammonium hydroxide may include tetramethylammonium hydroxide (TMAH), bis(2-hydroxyethyl) dimethylammonium hydroxide, tetraethylammonium hydroxide, tetrapropylammonium hydroxide, tetrabutylammonium hydroxide, methyltriethylammonium hydroxide, trimethyl (hydroxyethyl) ammonium hydroxide, triethyl (hydroxyethyl) ammonium hydroxide, tetrapentylammonium hydroxide, monomethyltripropylammonium hydroxide, trimethylethylammonium hydroxide, (2-hydroxyethyl) trimethylammonium hydroxide, (2-hydroxyethyl) triethylammonium hydroxide, (2-hydroxyethyl) tripropylammonium hydroxide, and (1-hydroxypropyl) trimethylammonium hydroxide.

Examples of the alkanolamine may include diisopropanolamine, aminoethylethanolamine, monoethanolamine, N-methyl ethanolamine, N-ethyl ethanolamine, N-propyl ethanolamine, N-butyl ethanolamine, diethanolamine, monoisopropanolamine, N-methyl isopropanolamine, N-ethyl isopropanolamine, N-propyl isopropanolamine, 2-aminopropan-1-ol, N-methyl-2-amino-propan-1-ol, N-ethyl-2-amino-propan-1-ol, 1-aminopropan-3-ol, N-methyl-1-aminopropan-3-ol, N-ethyl-1-aminopropan-3-ol, 1-aminobutan-2-ol, N-methyl-1-aminobutan-2-ol, N-ethyl-1-aminobutan-2-ol, 2-aminobutan-1-ol, N-methyl-2-aminobutan-1-ol, N-ethyl-2-aminobutan-1-ol, 3-aminobutan-1-ol, N-methyl-3-aminobutan-1-ol, N-ethyl-3-aminobutan-1-ol, 1-aminobutan-4-ol, N-methyl-1-aminobutan-4-ol, N-ethyl-1-aminobutan-4-ol, 1-amino-2-methylpropan-2-ol, 2-amino-2-methylpropan-1-ol, 1-aminopentan-4-ol, 2-amino-4-methylpentan-1-ol, 2-aminohexan-1-ol, 3-aminoheptan-4-ol, 1-aminooctan-2-ol, 5-aminooctan-4-ol, 1-aminopropane-2,3-diol, 2-aminopropane-1,3-diol, tris (oxymethyl) aminomethane, 1,2-diaminopropan-3-ol, 1,3-diaminopropan-2-ol, and 2-(2-aminoethoxy) ethanol.

Examples of other organic amines may include diazabicycloundecene.

Among the organic alkali compounds, a quaternary ammonium salt is preferable, an organic quaternary ammonium hydroxide is more preferable, and tetramethylammonium hydroxide is still more preferable.

Examples of the inorganic alkali compound may include ammonia, an inorganic compound containing an alkali metal or an alkaline earth metal, and salts thereof. Examples of the inorganic compound containing an alkali metal or an alkaline earth metal and a salt thereof may include lithium hydroxide, sodium hydroxide, potassium hydroxide, rubidium hydroxide, and cesium hydroxide. Among them, potassium hydroxide is preferable.

The alkali compounds may be used alone or in combination with two or more kinds thereof.

A content of the alkali compound in the processing solution according to the present embodiment is not particularly limited, and is preferably more than 10% by mass and 20% by mass or less. A lower limit value of the content is more preferably 11% by mass or more and still more preferably 12% by mass or more. In addition, an upper limit value of the content is more preferably 18% by mass or less and still more preferably 16% by mass or less. By setting the content of the alkali compound within the range described above, it is possible to further improve the balance between the removability of the metal components and the residues to be removed and the anticorrosion properties of the metal containing Cu atoms. Note that, when two or more kinds of alkali compounds are used in combination, the total amount of the alkali compounds is preferably within the range of the content described above.

A content of the organic alkali compound in the processing solution according to the present embodiment is not particularly limited, and is preferably more than 10% by mass and 20% by mass or less. A lower limit value of the content is more preferably 11% by mass or more and still more preferably 12% by mass or more. In addition, an upper limit value of the content is more preferably 18% by mass or less and still more preferably 16% by mass or less. By setting the content of the organic alkali compound within the range described above, it is possible to further improve the balance between the removability of the metal components and the residues to be removed and the anticorrosion properties of the metal containing Cu atoms. Note that, when two or more kinds of organic alkali compounds are used in combination, the total amount of the organic alkali compounds is preferably within the range of the content described above.

A content of the inorganic alkali compound in the processing solution according to the present embodiment is not particularly limited, and is preferably 0.01% by mass or more and 10% by mass or less. A lower limit value of the content is more preferably 0.05% by mass or more and still more preferably 0.1% by mass or more. In addition, an upper limit value of the content is more preferably 5% by mass or less and still more preferably 1% by mass or less. By setting the content of the inorganic alkali compound within the range described above, it is possible to further improve the balance between the removability of the metal components and the residues to be removed and the anticorrosion properties of the metal containing Cu atoms. Note that, when two or more kinds of inorganic alkali compounds are used in combination, the total amount of the inorganic alkali compounds is preferably within the range of the content described above.

### (Water)

The processing solution according to the present embodiment contains water. The water is preferably water from which metal ions, organic impurities, particles, and the like are removed by distillation, ion-exchange treatment, filter treatment, various adsorption treatments, or the like, or water having a reduced content of these components. As the water, for example, pure water, ultrapure water, deionized water (DIW), or the like can be used. The processing solution according to the present embodiment can be suitably used as a so-called aqueous processing solution (may also be referred to as a water-based processing solution or the like) by containing water as a solvent.

A content of the water can also be selected to be a suitable amount according to the kind or the like of the component to be processed and the use. Note that, in the preparation, required components other than water may be added, and then, water may be added as the balance.

The content of the water in the processing solution according to the present embodiment is preferably 50% by mass or more and 85% by mass or less. A lower limit value of the content is more preferably 52% by mass or more and still more preferably 55% by mass or more. An upper limit value of the content is more preferably 80% by mass or less and still more preferably 70% by mass or less. By setting the content of the water within the range described above, the advantages as an aqueous processing solution can be more effectively exhibited. In addition, by setting the content of the water within the range described above, it is possible to further improve the balance between the removability of the metal components and the residues to be removed and the anticorrosion properties of the metal containing Cu atoms.

### (Corrosion Inhibitor)

The processing solution according to the present embodiment contains a corrosion inhibitor. The corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof. Examples of these salts may include a sodium salt, a potassium salt, a calcium salt, a barium salt, an ammonium salt, and a tetraalkylammonium salt. Preferred examples of such a salt form may include sodium erythorbate. In addition, when the corrosion inhibitor is added, a hydrate can also be added.

A content of the corrosion inhibitor in the processing solution according to the present embodiment is not particularly limited, and is preferably 0.005% by mass or more and 5% by mass or less. A lower limit value of the content is more preferably 0.05% by mass or more and still more preferably 0.4% by mass or more. In addition, an upper limit value of the content is more preferably 2% by mass or less and still more preferably 1% by mass or less. By setting the content of the corrosion inhibitor within such a range, it is possible to further improve the balance between the anticorrosion properties of the metal containing Cu atoms and the removability of the metal components and the residues to be removed. Note that, when a hydrate is added as a corrosion inhibitor, it is preferable that the net content excluding the water of hydration contained in the hydrate is within the range described above.

### (Other Corrosion Inhibitors)

The processing solution according to the present embodiment may further contain a corrosion inhibitor other than the corrosion inhibitor described above. Examples of the other corrosion inhibitors may include compounds containing a nitrogen-containing heterocyclic ring such as a triazole ring, an imidazole ring, a pyridine ring, a phenanthroline ring, a tetrazole ring, a pyrazole ring, a pyrimidine ring, and a purine ring.

Examples of the compound containing a triazole ring may include triazoles such as 1,2,3-triazole, 1,2,4-triazole, 3-amino-1H-1,2,4-triazole, 1-acetyl-1H-1,2,3-triazolo[4,5-b]pyridine, 1H-1,2,3-triazolo[4,5-b]pyridine, 1,2,4-triazolo[4,3-a]pyridin-3 (2H)-one, and 3H-1,2,3-triazolo[4,5-b]pyridin-3-ol; and benzotriazoles such as 1,2,3-benzotriazole, 5-methyl-1H-benzotriazole, 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, and 3-aminotriazole.

Examples of the compound containing an imidazole ring may include imidazoles such as 2-methylimidazole, 2-ethylimidazole, 2-isopropylimidazole, 2-propylimidazole, 2-butylimidazole, 4-methylimidazole, 2,4-dimethylimidazole, 2-ethyl-4-methylimidazole, 2-undecylimidazole, and 2-aminoimidazole; and biimidazoles such as 2,2′-biimidazole.

Examples of the compound containing a pyridine ring may include pyridines such as 1H-1,2,3-triazolo[4,5-b]pyridine, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,6-pyridinecarboxylic acid, and 2,4,6-trimethylpyridine; and bipyridyls such as 2,2′-bipyridyl, 4,4′-dimethyl-2,2′-bipyridyl, 4,4′-di-tert-butyl-2,2′-bipyridyl, 4,4′-dinonyl-2,2′-bipyridyl, 2,2″-bipyridine-6,6′-dicarboxylic acid, and 4,4′-dimethoxy-2,2′-bipyridyl.

Examples of the compound containing a phenanthroline ring may include 1,10-phenanthroline.

Examples of the compound containing a tetrazole ring may include 1H-tetrazole, 5-amino-1H-tetrazole, 5-methyl-1H-tetrazole, 5-phenyl-1H-tetrazole, and 1-(2-diaminoethyl)-5-mercaptotetrazole.

Examples of the compound containing a pyrazole ring may include 3,5-dimethylpyrazole, 3-amino-5-methylpyrazole, 4-methylpyrazole, and 3-amino-5-hydroxypyrazole.

Examples of the compound containing a pyrimidine ring may include pyrimidine, 4-methylpyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxypyrimidine, 2,4-diaminopyrimidine, 2-acetamidopyrimidine, 2-aminopyrimidine, 2-methyl-5,7-diphenyl-(1,2,4) triazolo (1,5-a) pyrimidine, 2-methylsulfanyl-5,7-diphenyl-(1,2,4) triazolo (1,5-a) pyrimidine, 2-methylsulfanyl-5,7-diphenyl-4,7-dihydro-(1,2,4) triazolo (1,5-a) pyrimidine, and 4-aminopyrazolo[3,4-d]pyrimidine.

Examples of the compound containing a purine ring may include adenine, guanine, hypoxanthine, xanthine, uric acid, and theophylline.

The corrosion inhibitors may be used alone or in combination with two or more kinds thereof.

Note that, the processing solution according to the present embodiment can obtain sufficient anticorrosion properties without containing the corrosion inhibitor described above. For example, the processing solution according to the present embodiment may not contain one or more selected from the group consisting of compounds containing a nitrogen-containing heterocyclic ring (a triazole ring, an imidazole ring, a pyridine ring, a phenanthroline ring, a tetrazole ring, a pyrazole ring, a pyrimidine ring, a purine ring, or the like), ascorbic acids, catechols, saccharides, and polycarboxylic acids. The processing solution according to the present embodiment may not contain one or more selected from the group consisting of hydroquinone, catechol, 4-amino-3-methylphenol, sodium sulfite, and ammonium sulfite.

### (Antioxidant)

The processing solution according to the present embodiment may further contain an antioxidant. The antioxidant is not particularly limited, conventionally known antioxidants can be used, and examples thereof may include a phenol-based antioxidant, a hindered amine-based antioxidant, a phosphorus-based antioxidant, a sulfur-based antioxidant, and an alcohol amine-based antioxidant.

Examples of the phenol-based antioxidant may include hindered phenol-based antioxidants such as 4,4-thiobis (6-tert-butyl-m-cresol), 3,9-bis[2-[3-(3-tert-butyl-4-hydroxy-5-methylphenyl)-propionyloxy]-1,1-dimethylethyl]-2,4,8,10-tetraoxaspiro[5.5]undecane, 2,2′-methylenebis(6-tert-butyl-4-methylphenol), 2,2′-methylenebis(6-tert-butyl-4-ethylphenol), 4,4′-butylidenebis (6-tert-butyl-3-methylphenol), 4,4′-thiobis (6-tert-butyl-3-methylphenol), alkylated bisphenols, 2,6-di-tert-butyl-p-cresol, 2,6-di-tert-butyl-4-ethylphenol, 1,1,3-tris(2-methyl-4-hydroxy-5-tert-butylphenyl) butane, n-octadecyl-3-(3,5-di-tert-butyl-4-hydroxyphenyl)propionate, tetrakis [methylene-3-(3,5-di-tert-butyl-4-hydroxyphenyl)propionate]methane, tricthylene glycol bis[3-(3-tert-butyl-4-hydroxy-5-methylphenyl)propionate], and tris (3,5-di-tert-butyl-4-hydroxybenzyl) isocyanurate.

Examples of the hindered amine-based antioxidant may include bis(1,2,2,6,6-pentamethyl-4-piperidinyl) sebacate and 2-(3,5-di-tert-butyl-4-hydroxybenzyl)-2-n-butylmalonate bis(1,2,2,6,6-pentamethyl-4-piperidyl).

Examples of the phosphorus-based antioxidant may include tris (2,4-di-tert-butylphenyl) phosphite, tetrakis (2,4-di-tert-butylphenyl)-4,4′-biphenylene phosphite, trisnonylphenyl phosphite, bis(2,4-di-tert-butylphenyl) pentaerythritol diphosphite, and distearyl pentacrythritol diphosphite.

Examples of the sulfur-based antioxidant may include dilauryl 3,3-thiodipropionate, dimyristyl 3,3-thiodipropionate, distearyl 3,3-thiodipropionate, ditridecyl 3,3-thiodipropionate, pentaerythrityl tetrakis (3-lauryl thiodipropionate), and 2-mercaptobenzimidazole.

Examples of the alcohol amine-based antioxidant may include monoethanolamine, diethanolamine, triethanolamine, aminoethylethanolamine, tris-(hydroxyl-methyl) amino-methane, methyldiethanolamine, dimethylethanolamine, and N-methyldiethanolamine.

Among them, an alcohol amine-based antioxidant is preferable, and monoethanolamine is more preferable, from the viewpoint of oxidation prevention, thermal oxidation prevention, and odor suppression.

A content of the antioxidant in the processing solution according to the present embodiment is not particularly limited, and is preferably 0.001% by mass or more and 5% by mass or less. A lower limit value of the content is more preferably 0.05% by mass or more and still more preferably 0.2% by mass or more. In addition, an upper limit value of the content is more preferably 3% by mass or less, still more preferably 2% by mass or less, and further still more preferably 1% by mass or less. When the content is equal to or more than the lower limit value described above, a greater antioxidant effect can be obtained. In addition, when the content is equal to or less than the upper limit value described above, the substrate can be cleaned more efficiently.

### (Amount of Dissolved Oxygen)

In the processing solution according to the present embodiment, the amount of dissolved oxygen one week after the preparation of the processing solution (hereinafter, may be simply abbreviated as “the amount of dissolved oxygen after one week”) is 0.2 mg/L or more and 1.5 mg/L or less. In the processing solution according to the present embodiment, the amount of dissolved oxygen after one week is controlled to fall within such a range after blending the components described above, such that not only excellent removability of the metal components and the residues to be removed is achieved, but also corrosion (damage) to the metal containing Cu atoms can be suppressed. In the processing solution according to the present embodiment, it can be expected that the amount of dissolved oxygen after one week is more effectively controlled by appropriately controlling each component contained and the content thereof.

A lower limit value of the amount of dissolved oxygen after one week is preferably 0.25 mg/L or more, more preferably 0.30 mg/L or more, and still more preferably 0.35 mg/L or more. In addition, an upper limit value is preferably 1.49 mg/L or less. By setting the amount of dissolved oxygen after one week within the range described above, it is possible to further improve the balance between the removability of the metal components and the residues to be removed and the anticorrosion properties of the metal containing Cu atoms.

In addition, the amount of dissolved oxygen at the time of preparation of the processing solution (hereinafter, may be simply abbreviated as “the amount of dissolved oxygen at the time of preparation”) is not particularly limited, and is preferably 0.2 mg/L or more and 6 mg/L or less. A lower limit value of the amount of dissolved oxygen at the time of preparation is more preferably 0.22 mg/L or more and still more preferably 0.23 mg/L or more. In addition, an upper limit value is more preferably 5.8 mg/L or less and still more preferably 5.5 mg/L or less. In addition to controlling the amount of dissolved oxygen after one week, by controlling the amount of dissolved oxygen at the time of preparation so as to be within the range described above, it is possible to further improve the balance between the removability of the metal components and the residues to be removed and the anticorrosion properties of the metal containing Cu atoms. In the processing solution according to the present embodiment, it can be expected that the amount of dissolved oxygen at the time of preparation is more effectively controlled by appropriately controlling each component contained and the content thereof.

### (Other Components)

The processing solution according to the present embodiment may further contain optional components other than the components described above as long as the effects of the present embodiment can be obtained. As such optional components, a suitable component can be appropriately selected in consideration of the composition of the processing solution, the purpose of use, the material and configuration of the semiconductor substrate to be processed, and the like. Examples of the optional components may include a surfactant, a pH adjuster, and a buffer.

### (Surfactant)

The processing solution according to the present embodiment may contain a surfactant for preventing foaming and adjusting wettability of the processing solution to the substrate. Examples of the surfactant may include a nonionic surfactant, an anionic surfactant, a cationic surfactant, and an amphoteric surfactant.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, and an acetylene polyalkylene oxide-based surfactant.

These surfactants, which are generally commercially available, can be used. The surfactants may be used alone or in combination with two or more kinds thereof.

When the processing solution according to the present embodiment contains a surfactant, a content of the surfactant is not particularly limited, and is usually, for example, from 0.0001 to 5% by mass with respect to the total mass of the processing solution. When the content of the surfactant is within the range described above, bubbles generated by a foaming agent tend to be dense.

The processing solution according to the present embodiment may not contain one or more selected from the group consisting of a nonionic surfactant, an anionic surfactant, a cationic surfactant, and an amphoteric surfactant, and may not contain one or more of the compounds exemplified as these surfactants. The processing solution according to the present embodiment may not contain a surfactant.

### (pH Adjuster)

The processing solution according to the present embodiment may contain a pH adjuster. Examples of the pH adjuster may include an acidic compound and a basic compound. The basic compound may be an organic basic compound or an inorganic basic compound. However, the basic compound used as the pH adjuster is a compound other than the alkali compound used in the present embodiment. Examples of the pH adjuster may include methanesulfonic acid (MSA), phosphoric acid (H₃PO₄, H₄P₂O₇, and HPO₃), carboxylic acids, boric acid (H₃BO₃ and B(OH)₃), phosphorous acid (H₃PO₃), carbonic acid (H₂CO₃), orthocarbonate (H₄CO₄ and C(OH)₄CH₄O₄), sulfuric acid, and hydrochloric acid. The carboxylic acids are acids having at least one carboxy group (—COOH). As the carboxylic acids, monocarboxylic acids such as formic acid, acetic acid, propionic acid, butyric acid, and valeric acid; dicarboxylic acids such as oxalic acid, malonic acid, succinic acid, glutaric acid, and adipic acid; and tricarboxylic acids such as citric acid are preferable.

In addition, the processing solution according to the present embodiment may not contain a pH adjuster. For example, the processing solution according to the present embodiment may not contain one or more of the compounds exemplified as the pH adjuster, and may not contain one or more selected from the group consisting of methanesulfonic acid, phosphoric acid, carboxylic acids, boric acid, phosphorous acid, carbonic acid, orthocarbonate, sulfuric acid, and hydrochloric acid.

### (Buffer)

The processing solution according to the present embodiment may contain a buffer. The buffer is a compound having a mechanism of suppressing a change in pH of the solution. As the buffer, a compound having pH buffering ability can be appropriately used.

The buffers may be used alone or in combination with two or more kinds thereof. When the processing solution according to the present embodiment contains a buffer, a content of the buffer is not particularly limited, and is usually from 0.001 to 10% by mass with respect to the total mass of the processing solution. The processing solution according to the present embodiment may not contain a buffer.

(Organic solvent)

The processing solution according to the present embodiment may further contain an organic solvent. The kind of the organic solvent is not particularly limited, and an appropriate organic solvent can be selected in consideration of the kind and content of other components to be used. As the organic solvent, for example, an organic solvent miscible with an additive component such as the alkali compound, water, or corrosion inhibitor described above can be used. The organic solvent is preferably a water-soluble organic solvent.

Specific examples of the water-soluble organic solvent may include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol; ethers such as ethylene glycol monomethyl ether, ethylene glycol monoethyl ether, ethylene glycol monobutyl ether, diethylene glycol monomethyl ether, diethylene glycol monoethyl ether, and diethylene glycol monobutyl ether; acetates such as ethylene glycol monomethyl ether acetate and ethylene glycol monoethyl ether acetate; sulfoxides such as dimethyl sulfoxide (DMSO); sulfones such as dimethylsulfone, diethylsulfone, bis(2-hydroxyethyl) sulfone, and tetramethylene sulfone; amides such as N,N-dimethylformamide (DMF), N-methylformamide, N,N-dimethylacetamide, N-methylacetamide, and N,N-diethylacetamide; lactams such as N-methyl-2-pyrrolidone (NMP), N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; and lactones such as γ-butyrolactone and 8-valerolactone. Among them, sulfoxides are preferable, and dimethyl sulfoxide is more preferable.

These organic solvents may be used alone or in combination with two or more kinds thereof.

Note that, the processing solution according to the present embodiment is preferably an aqueous processing solution from the viewpoint of solubility of components, reduction in load on the environment, economic efficiency, and the like, and a preferred example of the aqueous processing solution is a processing solution in which a content of an organic solvent is lower than a content of water when the water and the organic solvent are contained. From such a viewpoint, the content of the organic solvent with respect to the total content of the water and the organic solvent is preferably 0.1% by mass or more and 50% by mass or less. An upper limit value of the content is more preferably 40% by mass or less and still more preferably 35% by mass or less. A lower limit value of the content may be 0.1% by mass or more or 1% by mass or more.

In addition, the content of the organic solvent in the processing solution according to the present embodiment is preferably 45% by mass or less, more preferably 40% by mass or less, still more preferably 35% by mass or less, further more preferably 30% by mass or less, and even still more preferably 28% by mass or less. By setting the content of the organic solvent within the range described above, the advantages as an aqueous processing solution can be more effectively exhibited. In addition, by setting the content of the organic solvent within the range described above, it is possible to further improve the balance between the removability of the metal components and the residues to be removed and the anticorrosion properties of the metal containing Cu atoms.

### (Impurities and the Like)

The processing solution according to the present embodiment may contain, for example, metal impurities including metal atoms such as Fe atoms, Cr atoms, Ni atoms, Zn atoms, Ca atoms, and Pb atoms. The total content of the metal atoms in the processing solution according to the present embodiment is preferably 100 ppt by mass or less with respect to the total mass of the processing solution. A lower limit value of the total content of the metal atoms is preferably as low as possible, and is, for example, 0.001 ppt by mass or more. The total content of the metal atoms is, for example, 0.001 ppt by mass to 100 ppt by mass. By setting the total content of the metal atoms to be equal to or less than the above-described preferred upper limit value, defect suppressing property and residue suppressing property of the processing solution are improved. It is considered that when the total content of the metal atoms is set to be equal to or more than the above-described preferred lower limit value, the metal atoms hardly exist in the system separately, and the manufacturing yield of the entire target to be cleaned is hardly adversely affected.

A content of the metal impurities can be adjusted, for example, by a purification process such as filtering. The purification process such as filtering may be performed on a part or all of the raw materials before preparing the processing solution or may be performed after the processing solution is prepared.

The processing solution according to the present embodiment may contain, for example, impurities derived from organic substances (organic impurities). The total content of the organic impurities in the processing solution according to the present embodiment is preferably 5,000 ppm by mass or less. A lower limit value of the content of the organic impurities is preferably as low as possible, and is, for example, 1 ppq by mass or more. Examples of the total content of the organic impurities may include 1 ppq by mass to 5,000 ppm by mass.

The processing solution according to the present embodiment may contain, for example, targets to be counted having a size countable by a light scattering type in-liquid particle counter. The size of the target to be counted is, for example, 0.04 μm or more. The number of the targets to be counted in the processing solution according to the present embodiment per 1 mL of the processing solution is, for example, 1,000 or less, and a lower limit value is, for example, 0.1 or more. It is considered that, when the number of targets to be counted in the processing solution is within the range described above, the effect of preventing metal corrosion, the effect of reducing defects, and the like by the processing solution are improved (however, the mechanism and effect of the present embodiment are not limited thereto).

The size of the target to be counted may be a size detectable by a light scattering type in-liquid particle counter and may be, for example, 0.001 μm or more.

The organic impurities and/or the targets to be counted described above may be added to the processing solution or may be inevitably mixed into the processing solution in a manufacturing process of the processing solution. Examples of cases where the organic impurities are inevitably mixed in the manufacturing process of the processing solution may include a case where the organic impurities are included in a raw material (for example, an organic solvent) used for manufacturing the processing solution, and a case where the organic impurities are mixed from an external environment in the manufacturing process of the processing solution (for example, contamination), and the embodiment is not limited thereto.

When the targets to be counted are added to the processing solution, an abundance ratio may be adjusted for each specific size considering surface roughness and the like of the object to be cleaned.

### <Method for Manufacturing Processing Solution>

A method for manufacturing a processing solution according to the present embodiment is a method for manufacturing a processing solution, the method including: a preparation step of preparing a processing solution by mixing an alkali compound, water, and a corrosion inhibitor, in which the amount of dissolved oxygen one week after the preparation (completion of the preparation step) of the processing solution is 0.2 mg/L or more and 1.5 mg/L or less, and the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof.

As the alkali compound, the water, and the corrosion inhibitor, each component described above for the processing solution can be used. For example, in the preparation step, it goes without saying that other components other than the alkali compound, the water, and the corrosion inhibitor may be mixed as raw materials as necessary. As raw materials of the processing solution, commercially available products can be used. In addition, these raw materials may be subjected to a purification process as necessary. The mixing method performed in the preparation step is not particularly limited, and raw materials can be mixed by a known method.

The amount of dissolved oxygen one week after the preparation of the processing solution (the amount of dissolved oxygen after one week) is 0.2 mg/L or more and 1.5 mg/L or less. For the amount of dissolved oxygen after one week, the content described above for the processing solution can be adopted. For example, a lower limit value of the amount of dissolved oxygen after one week is preferably 0.25 mg/L or more, more preferably 0.3 mg/L or more, and still more preferably 0.35 mg/L or more. In addition, an upper limit value is preferably 1.49 mg/L or less. By setting the amount of dissolved oxygen after one week within the range described above, it is possible to further improve the balance between the removability of the metal components and the residues to be removed and the anticorrosion properties of the metal containing Cu atoms.

The amount of dissolved oxygen when performing the preparation step is preferably 0.2 mg/L or more and 6 mg/L or less. The “amount of dissolved oxygen when performing the preparation step” is the “amount of dissolved oxygen at the time of preparation” described for the processing solution. Therefore, as for the matter related to the “amount of dissolved oxygen when performing the preparation step”, the content of the “amount of dissolved oxygen at the time of preparation” described above can be adopted unless otherwise specified. For example, a lower limit value of the amount of dissolved oxygen when performing the preparation step is preferably 0.22 mg/L or more and more preferably 0.23 mg/L or more. For example, an upper limit value of the amount of dissolved oxygen when performing the preparation step is more preferably 5.8 mg/L or less and still more preferably 5.5 mg/L or less. In addition to controlling the amount of dissolved oxygen after one week, by controlling the amount of dissolved oxygen when performing the preparation step so as to be within the range described above, it is possible to further improve the balance between the removability of the metal components and the residues to be removed and the anticorrosion properties of the metal containing Cu atoms.

The processing solution according to the present embodiment is not only excellent in removability of metal components and residues to be removed, but also excellent in anticorrosion properties of a metal containing Cu atoms. Therefore, the processing solution according to the present embodiment can be suitably used for processing a metal layer containing Cu atoms and/or a substrate containing Cu atoms. An example of the substrate to be processed with the processing solution according to the present embodiment will be described below.

In a semiconductor device, a substrate, a metal wiring layer, an etching stop layer, and an interlayer insulating film are laminated in this order, and a protective film (hard mask layer, HM layer) is laminated on the interlayer insulating film. The processing solution according to the present embodiment can be used for processing a laminated substrate used in the manufacture of such a semiconductor device. The structure of the laminated substrate before processing is not particularly limited, and for example, a laminated substrate having a metal layer corresponding to a metal wiring layer, an etching stop layer, an interlayer insulating film, or the like as the metal layer laminated on the substrate is exemplified.

Examples of the material of the substrate may include substrate materials such as silicon, amorphous silicon, polysilicon, and glass.

Examples of the metal wiring layer may include metal wiring layers containing at least one selected from the group consisting of metals such as tungsten (W), molybdenum (Mo), cobalt (Co), ruthenium (Ru), gold (Au), silver (Ag), copper (Cu), iron (Fe), nickel (Ni), aluminum (Al), lead (Pb), zinc (Zn), tin (Sn), tantalum (Ta), magnesium (Mg), bismuth (Bi), cadmium (Cd), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), and thallium (Tl), and metal oxides, metal nitrides, metal chlorides, and metal fluorides thereof. From the viewpoint of effectively utilizing the advantages of the present embodiment, a metal wiring layer containing Cu is preferable.

Note that the metal wiring layer is not limited to a wiring shape, and widely includes functional layers such as an electrode, an insulating layer, a low-dielectric layer, a barrier layer, and various conductor layers. The metal layer includes layers formed by using the various metals described above, and metal oxides, metal nitrides, metal chlorides, and metal fluorides thereof. Therefore, the substrate having a metal layer also includes a substrate including a metal wiring layer and the like. Examples of the functional layer other than the metal layer may include a silicon-based functional layer. Examples of the silicon-based film may include SiO₂, SiN, SiOCN, and Low-k films (SiOC films, SiCOH films, and the like) described below.

Examples of the material of the etching stop layer may include aluminum oxide, SiN, SiON, and SiOCN.

Examples of the material of the interlayer insulating film may include silicon-based materials such as SiO₂, SiN, and SiOCN. The interlayer insulating film can be used, for example, as a functional layer that insulates wiring between multilayer wirings including a plurality of layers. In addition, in accordance with the recent miniaturization of wiring, a “Low-k material” having a low dielectric constant is used for the interlayer insulating film, and SiOC, SiOCH, and the like are exemplified.

The material of the protective film (hard mask layer, HM layer) may be any material as long as it functions as a protective film against etching, the material is not particularly limited, and a suitable material can be appropriately selected in consideration of manufacturing conditions and the like. Examples of the material of the protective film may include titanium-based materials such as Ti and TiN, silicon-based materials such as SIN, SiO₂, SiON, and SiCN, and combinations thereof.

In addition, in the manufacturing process of the semiconductor device, a resist material containing a polymer as a main component, an embedding material containing an alkoxysilane material or the like as a main component, or the like is also used as necessary in order to form wiring.

The processing solution according to the present embodiment can be suitably used as a processing solution for processing a substrate having a metal layer. As a preferred aspect, the processing solution is a processing solution for processing a substrate having a metal layer, and the substrate and/or the metal layer contain Cu atoms. The processing solution according to the present embodiment is excellent not only in the removability of the metal components and the residues to be removed but also in the anticorrosion properties of the metal containing Cu atoms. Therefore, in the processing of the metal layer containing Cu atoms and/or the substrate containing Cu atoms, the resist film, the embedding material, and the residues can be effectively removed, and damage (corrosion) to the substrate having the metal layer containing Cu atoms and the substrate containing Cu atoms can be effectively prevented. Therefore, the processing solution according to the present embodiment can also be expected to be suitably used for manufacturing a semiconductor device having such a structure.

In addition, as a preferred aspect of the processing solution according to the present embodiment, there is a processing solution used for removing residues generated after an etching process is performed on a substrate having a metal layer. Normally, the etching residues are removed before the next step from the viewpoint of improving the yield of the semiconductor and preventing deterioration of electrical characteristics. The processing solution according to the present embodiment is suitable for processing a semiconductor substrate after dry etching is performed by a wiring forming process. For example, the processing solution according to the present embodiment can be suitably used when removing residues generated after etching of a substrate having a metal layer containing Cu atoms or a substrate containing Cu atoms in a manufacturing process of a semiconductor device.

### <Method for Processing Substrate>

The processing solution according to the present embodiment can be suitably used in a method for processing a semiconductor substrate. Preferred examples of a method for processing a substrate according to the present embodiment may include a method for processing a substrate, the method including: (1) preparing a substrate having a metal layer; (2) etching the metal layer; and (3) after the etching, bringing the processing solution into contact with the substrate to remove impurities from the substrate. Hereinafter, a case where a laminated substrate used for manufacturing a semiconductor device is processed will be described as an example.

### (1) Step of Preparing Substrate Having Metal Wiring Layer

In step (1), a substrate having at least a metal layer is prepared. The metal layer is not particularly limited as long as it is a layer containing a metal, and examples thereof may include various metal layers, an etching stop layer, an interlayer insulating film, and a hard mask layer (HM layer) corresponding to a protective film. A method for sequentially laminating the metal layer, the etching stop layer, the interlayer insulating film, and/or the hard mask layer (HM layer) corresponding to the protective film on the substrate is not particularly limited, and a known method can be adopted.

### (2) Step of Etching Metal Layer

Subsequently, the metal layer is etched. The etching method is not particularly limited, and may be wet etching or dry etching, but is preferably dry etching. In the case of dry etching, it is advantageous from the viewpoint that metal wiring at a nano level is possible and gas to be used can be controlled.

In the case of dry etching, plasma can be used. Usually, when plasma etching is performed, there is a problem that the substrate is easily damaged, or a problem that plasma etching residues are generated and it is necessary to clean the plasma etching residues with a processing solution. However, the processing solution according to the present embodiment can achieve both the anticorrosion properties and removability described above, such that such a problem can be effectively suppressed.

(3) Step of Removing Impurities from Substrate by Bringing Processing Solution into Contact with Substrate after Etching.

The processing method in step (3) is not particularly limited, and a known processing method can be used. Examples of the processing operation may include a method of continuously applying the processing solution on the laminated substrate of the semiconductor device rotating at a constant speed (rotational application method), a method of immersing the laminated substrate of the semiconductor device in the processing solution for a certain period of time (dipping method), and a method of spraying the processing solution on a surface of the laminated substrate of the semiconductor device (spraying method).

In addition, when the processing solution is brought into contact with the substrate (laminated substrate) to be processed, an operation of diluting the processing solution by 2 to 2,000 times to obtain a diluted solution and then performing processing using the diluted solution may be performed.

A processing temperature (temperature of the processing solution) is not particularly limited, and is preferably from 10 to 80° C. A lower limit value of the processing temperature is more preferably 20° C. or higher and still more preferably 40° C. or higher. In addition, an upper limit value of the processing temperature is more preferably 75° C. or lower and still more preferably 70° C. or lower. By setting the lower limit value of the processing temperature within the range described above, it is possible to further improve the removability of the etching residues while suppressing damage to the metal containing Cu atoms. In addition, by setting the upper limit value of the processing temperature within the range described above, it is possible to more effectively suppress an unintended composition change of the processing solution, and it is possible to more efficiently clean the substrate from the viewpoint of workability, safety, cost, and the like.

As the processing time, the time required for removing residues, impurities, and the like adhering to the surface of the substrate (laminated substrate) to be processed can be appropriately selected. The processing time is not particularly limited, and is preferably from 10 seconds to 30 minutes. A lower limit value of the processing time is more preferably from 20 seconds or longer and still more preferably from 30 seconds or longer. In addition, an upper limit value of the processing time is more preferably 15 minutes or shorter, still more preferably 10 minutes or shorter, and further still more preferably 5 minutes or shorter.

### <Method for Manufacturing Semiconductor Device>

Preferred examples of a method for manufacturing a semiconductor device according to the present embodiment may include a method for manufacturing a semiconductor device, the method including: preparing a substrate having a metal layer; etching the metal layer; and after the etching, bringing the processing solution described above into contact with the substrate to remove impurities from the substrate. As for the matters related to each of these steps, the matters described in the method for processing a substrate described above can be appropriately adopted unless otherwise specified.

According to the method for manufacturing a semiconductor device of the present embodiment, it is possible to obtain a high-quality semiconductor device in which residues and impurities are sufficiently removed and damage to a metal layer or a substrate to be protected is sufficiently suppressed. In particular, since it is possible to achieve both the removability of metal components and residues to be removed and the anticorrosion properties of a metal containing Cu atoms, it is suitable for the manufacture of a semiconductor device having a metal layer and/or substrate containing Cu atoms.

As described above, according to the processing solution, the method for processing a substrate, and the method for manufacturing a semiconductor device according to the present embodiment, it is possible to achieve both the removability of metal components and residues to be removed and the anticorrosion properties of a metal containing Cu atoms. Therefore, it is possible to remove a resist film, an embedding material, and a metal residue while suppressing corrosion (damage) of the metal layer containing Cu atoms and the substrate containing Cu atoms. Even when a substrate having a metal layer containing Cu atoms or a substrate containing Cu atoms is processed, it is possible to suppress damage to the metal layer or the substrate while sufficiently removing removal targets and residues such as a resist film and an embedding material, and thus, it is possible to manufacture a high-quality semiconductor device.

### EXAMPLES

Hereinafter, the present invention will be described in more detail with reference to examples, but the present invention is not limited by these examples.

### (Preparation of Processing Solution)

Each component was mixed to obtain the composition shown in Table 1 to prepare a processing solution. For example, in the case of Comparative Example 1, the processing solution contains 0.10% by mass of KOH, 12.10% by mass of TMAH, 27.00% by mass of DMSO, 60.30% by mass of DIW, and 0.50% by mass of MEA, and does not contain a corrosion inhibitor, the amount of dissolved oxygen at the time of preparation of the processing solution is 3.16 mg/L, and the amount of dissolved oxygen one week after the preparation of the processing solution is 2.3 mg/L. In the case of Example 1, the processing solution contains 0.10% by mass of KOH, 12.10% by mass of TMAH, 26.90% by mass of DMSO, 60.00% by mass of DIW, 0.50% by mass of MEA, and 0.50% by mass of N,N-diethylhydroxylamine, the amount of dissolved oxygen at the time of preparation of the processing solution is 1.04 mg/L, and the amount of dissolved oxygen one week after the preparation of the processing solution is 0.36 mg/L. Note that the contents (% by mass) of hydrates such as ammonium sulfite monohydrate and sodium erythorbate monohydrate are shown in Table 1 as the contents excluding the water of hydration contained in the hydrates (the contents of ammonium sulfite and sodium erythorbate).

Note that abbreviations and the like described in Table 1 are as follows.
KOH: potassium hydroxide
TMAH: tetramethylammonium hydroxide
DMSO: dimethyl sulfoxide
DIW: deionized water
MEA: monoethanolamine

### (Amount of Dissolved Oxygen in Processing Solution)

The amount of dissolved oxygen in the processing solution to be measured was measured at 25° C. in the air atmosphere using an oxygen concentration meter (“B-506” manufactured by Samejima Electronics Industry Co., Ltd.).

First, as the amount of dissolved oxygen at the time of preparation of the processing solution (“the amount of dissolved oxygen (at the time of preparation)”), the amount of dissolved oxygen in the processing solution immediately after preparation was measured by the above method.

Next, the amount of dissolved oxygen one week after the preparation (“the amount of dissolved oxygen (after one week)”) was measured under the following conditions. First, the processing solution immediately after preparation was placed in a high-density polyethylene bottle, sealed in a nitrogen gas atmosphere, and stored in a dark place at 25° C. for one week. Thereafter, the amount of dissolved oxygen was measured by the above method.

### (Evaluation of Removability of Residues)

First, a Cu pattern wafer having a metal layer of SiN, an interlayer insulating layer, an etching stop layer, and a metal layer of Cu (CuPTW (Cu substrate/SiN layer/interlayer insulating layer/etching stop layer/Cu layer)) formed on a Cu substrate (2 cm×2 cm) was obtained by a CVD method, and used as a sample. Note that the components contained in the interlayer insulating layer were Si, Oₓ, and C_{y} (x and y each independently represent 0 or a natural number), and the components contained in the etching stop layer were Si, Oₓ, C_{y}, and N_{z} (x, y, and z each independently represent 0 or a natural number).

Then, 100 mL of the processing solution of each example and each comparative example was placed in a cup. The sample was put therein and immersed at 58° C. for 3 minutes. Note that, during the immersion, the processing solution was stirred at 1,000 rpm. After immersion, the sample was removed from the processing solution, washed with water at room temperature for 30 seconds, and dried by nitrogen blow. Then, the removability of residues was evaluated according to the following criteria. The residues were observed using a scanning electron microscope (20,000× magnification).
A: Residues were not observed on the surface.
B: Residues were observed in a region of less than half of the surface.
C: Residues were observed in a region of half or more of the surface.
D: The initial pattern was not observed.

The evaluation results of all of the examples were A. On the other hand, the evaluation result of Comparative Example 1 was D, and the evaluation result of each of Comparative Examples 2 to 6 was C.

### (Evaluation of Anticorrosion Properties)

A Cu pattern wafer (CuPTW, (Cu substrate/SiN layer/interlayer insulating layer/etching stop layer/Cu layer)) prepared in the above-described “(Evaluation of removability of residues)” section was used as a sample.

Then, 100 mL of the processing solution of each example and each comparative example was placed in a cup. The sample was put therein and immersed at 58° C. for 3 minutes. Note that, during the immersion, the processing solution was stirred at 1,000 rpm. After immersion, the sample was removed from the processing solution, washed with water at room temperature for 30 seconds, and dried by nitrogen blow. Then, the anticorrosion properties were evaluated according to the following criteria. The anticorrosion properties were observed using a scanning electron microscope (20,000× magnification).
A: Corrosion was not observed on the surface.
B: Corrosion was observed in a region of less than half of the surface.
C: Corrosion was observed in a region of half or more of the surface.

Table 1 shows compositions, evaluation results, and the like of the processing solutions of each example and each comparative example.

TABLE 1

| | Alkali compound | | | | Solvent | | | | Antioxidant | | Corrosion inhibitor |
|---|---|---|---|---|---|---|---|---|---|---|---|
| | (% by mass) | | | | (% by mass) | | | | (% by mass) | | (% by mass) |
| Comparative | KOH | 0.10 | TMAH | 12.10 | DMSO | 27.00 | DIW | 60.30 | MEA | 0.50 | — |
| Example 1 | | | | | | | | | | | |
| Example 1 | KOH | 0.10 | TMAH | 12.00 | DMSO | 26.90 | DIW | 60.00 | MEA | 0.50 | N,N-Diethylhydroxylamine |
| Example 2 | KOH | 0.10 | TMAH | 12.00 | DMSO | 26.90 | DIW | 60.00 | MEA | 0.50 | 1-Thioglycerol |
| Comparative | KOH | 0.10 | TMAH | 12.00 | DMSO | 26.90 | DIW | 60.00 | MEA | 0.50 | Hydroquinone |
| Example 2 | | | | | | | | | | | |
| Comparative | KOH | 0.10 | TMAH | 12.00 | DMSO | 26.90 | DIW | 60.00 | MEA | 0.50 | Catechol |
| Example 3 | | | | | | | | | | | |
| Example 3 | KOH | 0.10 | TMAH | 12.00 | DMSO | 26.90 | DIW | 60.00 | MEA | 0.50 | 1-Amino-4-methylpiperazine |
| Comparative | KOH | 0.10 | TMAH | 12.00 | DMSO | 26.90 | DIW | 60.00 | MEA | 0.50 | 4-Amino-3-methylphenol |
| Example 4 | | | | | | | | | | | |
| Comparative | KOH | 0.10 | TMAH | 12.00 | DMSO | 26.90 | DIW | 60.00 | MEA | 0.50 | Sodium sulfite |
| Example 5 | | | | | | | | | | | |
| Comparative | KOH | 0.10 | TMAH | 12.00 | DMSO | 26.90 | DIW | 60.00 | MEA | 0.50 | Ammonium sulfite |
| Example 6 | | | | | | | | | | | monohydrate |
| Example 4 | KOH | 0.10 | TMAH | 12.00 | DMSO | 26.90 | DIW | 60.00 | MEA | 0.50 | Carbohydrazide |
| Example 5 | KOH | 0.10 | TMAH | 12.00 | DMSO | 26.90 | DIW | 60.00 | MEA | 0.50 | Methylethylketoxime |
| Example 6 | KOH | 0.10 | TMAH | 12.00 | DMSO | 26.90 | DIW | 60.00 | MEA | 0.50 | Sodium erythorbate |
| | | | | | | | | | | | monohydrate |

| | | Amount of | Amount of | |
|---|---|---|---|---|
| | | dissolved | dissolved | |
| | | oxygen (at | oxygen | |
| | | the time of | (after | |
| | Corrosion inhibitor | preparation) | one week) | Anticorrosion |
| | (% by mass) | (mg/L) | (mg/L) | properties |
| Comparative | — | 3.16 | 2.3 | C |
| Example 1 | | | | |
| Example 1 | 0.50 | 1.07 | 0.36 | A |
| Example 2 | 0.50 | 2.98 | 1.47 | A |
| Comparative | 0.50 | 0.26 | 0.25 | C |
| Example 2 | | | | |
| Comparative | 0.50 | 0.24 | 0.24 | B |
| Example 3 | | | | |
| Example 3 | 0.50 | 5.41 | 1.4 | A |
| Comparative | 0.50 | 0.26 | 0.22 | B |
| Example 4 | | | | |
| Comparative | 0.50 | 5.14 | 1.83 | C |
| Example 5 | | | | |
| Comparative | 0.50 | 5.22 | 2.56 | C |
| Example 6 | | | | |
| Example 4 | 0.50 | 0.59 | 0.51 | A |
| Example 5 | 0.50 | 5.33 | 1.48 | A |
| Example 6 | 0.50 | 0.24 | 0.24 | A |

From the above, it was confirmed, at least, that the processing solution according to the present embodiment is not only excellent in removability of metal components and residues to be removed, but also excellent in anticorrosion properties of a metal containing Cu atoms.

What is claimed is:

1. A processing solution comprising an alkali compound, water, and a corrosion inhibitor,
wherein the amount of dissolved oxygen one week after the preparation of the processing solution is 0.2 mg/L or more and 1.5 mg/L or less, and
the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof.

2. The processing solution according to claim 1, further comprising an antioxidant.

3. The processing solution according to claim 1, wherein
a content of the alkali compound is more than 10% by mass and 20% by mass or less.

4. The processing solution according to claim 1, wherein
a content of the water is 50% by mass or more and 85% by mass or less.

5. The processing solution according to claim 1, wherein
a content of the corrosion inhibitor is 0.005% by mass or more and 5% by mass or less.

6. The processing solution according to claim 2, wherein
a content of the antioxidant is 0.001% by mass or more and 5% by mass or less.

7. The processing solution according to claim 1, wherein
the amount of dissolved oxygen at the time of preparation of the processing solution is 0.2 mg/L or more and 6 mg/L or less.

8. The processing solution according to claim 1, wherein
the processing solution is a processing solution for processing a substrate having a metal layer, and
the substrate and/or the metal layer contain Cu atoms.

9. The processing solution according to claim 8, wherein
the processing solution is used for removing a residue generated after an etching process is performed on the substrate having the metal layer.

10. A method for manufacturing a processing solution, the method comprising:
a preparation step of preparing a processing solution by mixing an alkali compound, water, and a corrosion inhibitor,
wherein the amount of dissolved oxygen one week after the preparation of the processing solution is 0.2 mg/L or more and 1.5 mg/L or less, and
the corrosion inhibitor is at least one selected from the group consisting of N,N-diethylhydroxylamine, 1-thioglycerol, 1-amino-4-methylpiperazine, carbohydrazide, methylethylketoxime, erythorbic acid, and salts thereof.

11. The method for manufacturing a processing solution according to claim 10, wherein
the amount of dissolved oxygen when performing the preparation step of the processing solution is 0.2 mg/L or more and 6 mg/L or less.

12. A method for processing a substrate, the method comprising:
preparing a substrate having a metal layer;
etching the metal layer; and
after the etching, bringing the processing solution according to claim 1 into contact with the substrate to remove impurities from the substrate.

13. A method for manufacturing a semiconductor device, the method comprising:
preparing a substrate having a metal layer;
etching the metal layer; and
after the etching, bringing the processing solution according to claim 1 into contact with the substrate to remove impurities from the substrate.
